(19) United States
(12) Patent Application Publication
(10) Pub. No.: US 2008/0174974 A1
(43) Pub. Date: Jul. 24, 2008

(54) Keylock structure and electronic device using the same

(75) Inventors: Chien-Ming Hung, Taipei (TW); Shen-Yuan Lee, Taipei (TW); Yuan Yu, Taipei (TW); Mei-Jui Lin, Taipei (TW); Wen-Huei Su, Taipei (TW)

Correspondence Address: BACON & THOMAS, PLLC, 625 SLATERS LANE, FOURTH FLOOR, ALEXANDRIA, VA, 22314, US

(73) Assignee: ASUSTek COMPUTER INC., Taipei (TW)

(21) Appl. No.: 12/007,727

(22) Filed: Jan. 15, 2008

(30) Foreign Application Priority Data
Jan. 18, 2007 (TW) 96101961

(51) Int. Cl. H05K 7/00

(52) U.S. Cl. 361/747

(57) ABSTRACT

A keylock structure and an electronic device using the same are provided. The electronic device includes a first casing and a second casing. The keylock structure includes a body and a hook. The hook and the body are connected with each other and form a concave portion. When the hook passes through a through hole of the first casing, the concave portion is fastened at the through hole. When the second casing is assembled to the first casing, a circuit switch in the second casing is embedded into a recess of the hook and is fixed to the same, such that the circuit switch is combined with the keylock structure.

### BACKGROUND OF THE INVENTION

This application claims the benefit of Taiwan application Serial No. 96101961, filed Jan. 18, 2007, the subject matter of which is incorporated herein by reference.

### FIELD OF THE INVENTION

The invention relates to a keylock structure and an electronic device using the same and, more particularly, to a keylock structure which has a simple structure and can be assembled easily and an electronic device using the same.

### DESCRIPTION OF THE RELATED ART

Nowadays, most of the handheld electronic device such as the personal digital assistant or communication mobile phone sold on the market has a keylock structure to lock the electronic components such as the screen and the keyboard of the electronic device to avoid that users activate the electronic components by mistake when they do not operate the electronic device.

Please refer to FIG. 1A and FIG. 1B. FIG. 1A is a schematic diagram showing part of a conventional electronic device assembled with a keylock structure. FIG. 1B is schematic diagram showing the back of the keylock structure shown in FIG. 1A. As shown in FIG. 1A, the electronic device 1 is composed of a first component 11 and a second component 13. The keylock structure 15 of the electronic device 1 is placed on a through hole 17 of one of the components such as the first component 11 and is not located in the electronic device 1 until the second component 13 is assembled. As shown in FIG. 1B, the conventional keylock structure 15 mainly includes a body 19 and a skirt 21 connected to the body 19. The body 19 is used as an interface where the whole keylock structure 15 slides, and the skirt 21 is used to slide on the inner wall of the first component 11. When assembled, the body 19 of the keylock structure 15 must pass through the through hole 17 of the first component 11, and the keylock structure 15 is temporarily located on the first component 11 by sticky tape to avoid losing the keylock structure 15. Usually, other structures such as a plurality of ribs are designed at the second component 13. When the second component 13 is assembled to the first component 11, the ribs are against the external side of the skirt 21 of the keylock structure 15 to prevent the keylock structure 15 from falling from the first component 11 and falling into the electronic device 1.

However, the keylock structure 15 can be located only by the combination of the first component 11 and the second component 13. Thus, the structure design of the second component 13 is complex. Furthermore, the sticky tape has to be used to temporarily locate the keylock structure 15 in the first component 11 in assembly, which wastes much unnecessary material and increases the whole assembly time.

### BRIEF SUMMARY OF THE INVENTION

The invention provides a keylock structure and an electronic device using the same. The keylock structure can be directly combined with a casing of an electronic device via the design of hook and concave portion, and the keylock structure can be fixed at the electronic device before another casing is assembled. A circuit switch of the electronic device is directly embedded into the keylock structure when the second casing is assembled to be combined with the keylock structure.

The invention provides a keylock structure applied to an electronic device. The electronic device includes a first casing. The keylock structure includes a body and a hook which are connected with each other, and a concave portion is formed between the body and the hook. When the hook passes through a through hole of the first casing, the concave portion is fastened at the through hole.

The invention also provides an electronic device including a first casing and a keylock structure. The first casing has a through hole. The keylock structure includes a body and a hook connected to the body, and a concave portion is formed between the body and the hook. The hook can pass through a through hole of the first casing to make the concave portion fastened at the through hole.

These and other features, aspects, and advantages of the present invention will become better understood with regard to the following description, appended claims, and accompanying drawings.

### BRIEF DESCRIPTION OF THE DRAWINGS

FIG. 1A is a schematic diagram showing part of a conventional electronic device assembled with a keylock structure.

FIG. 1B is a schematic diagram showing the back of the keylock structure shown in FIG. 1A.

FIG. 2A is an exploded diagram showing an electronic device according to a preferred embodiment of the invention.

FIG. 2B is partial enlarged diagram showing the electronic device shown in FIG. 2A.

FIG. 3 is a schematic diagram showing the keylock structure shown in FIG. 2A.

FIG. 4A and FIG. 4B are section diagrams showing the keylock structure assembled to the first casing shown in FIG. 2B.

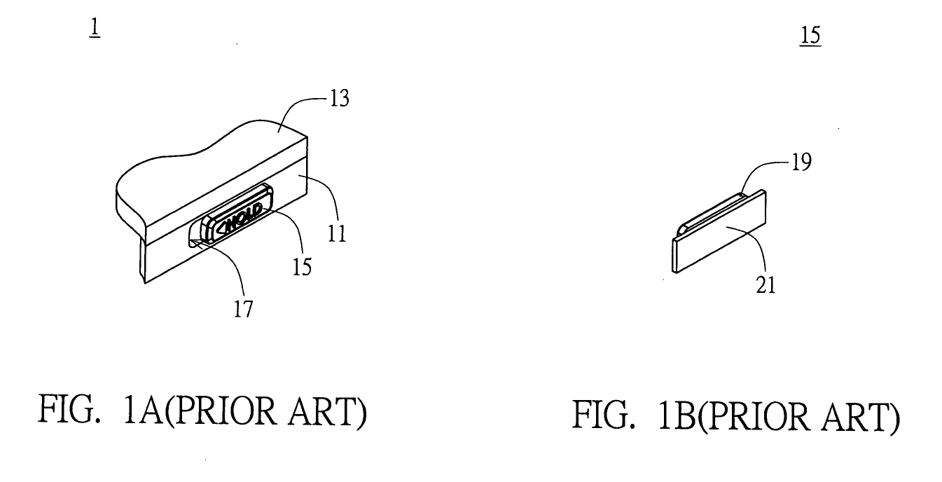

### DETAILED DESCRIPTION OF THE EMBODIMENT

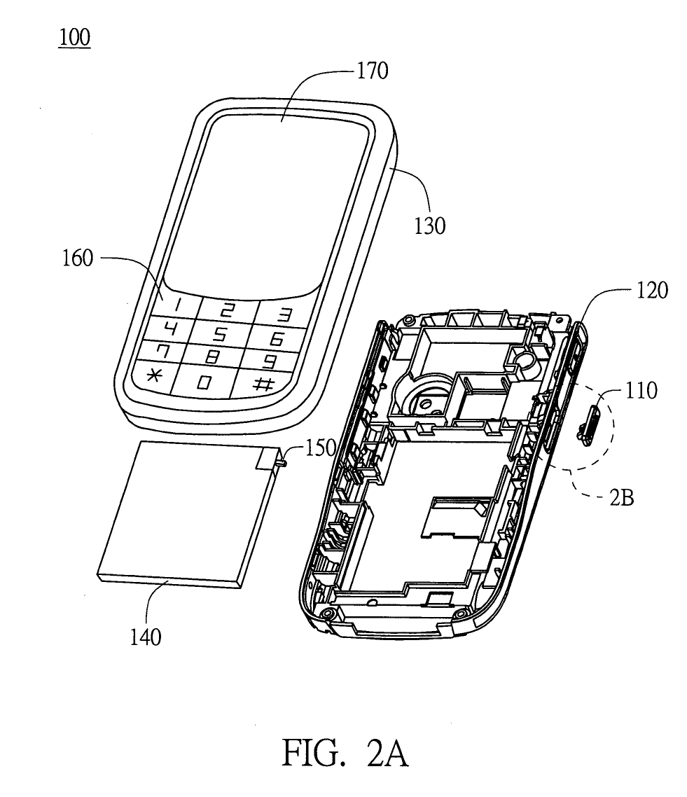

Please refer to FIG. 2A and FIG. 2B. FIG. 2A is an exploded diagram showing an electronic device according to a preferred embodiment of the invention. FIG. 2B is a partial enlarged diagram showing the electronic device shown in FIG. 2A. As shown in FIG. 2A and FIG. 2B, the electronic device 100 includes a keylock structure 110 and a first casing 120. The keylock structure 110 includes a body 111 and a hook 113. The hook 113 is connected to the body 111, and a concave portion 115 is formed between the hook 113 and the body 111. The first casing 120 has a through hole 122. When the hook 113 passes through the through hole 122 of the first casing 120, the casing plate of the first casing 120 is embedded into the concave portion 115 to make the body 111 of the keylock structure 110 combine with the first casing 120.

As shown in FIG. 2A, the electronic device 100 further includes a second casing 130, a circuit board 140 and a circuit switch 150. The circuit switch 150 is electrically connected to the circuit board 140 and is provided in the second casing 130. The circuit board 130 is electrically connected to other electronic components of the electronic device 100. The circuit switch 150 is used to control the usage status of the electronic components of the electronic device 100. After the second casing 130 is assembled to the first casing 120, the circuit switch 150 is combined with the keylock structure 110. If a user does not use the electronic device 100 in a short term, and the electronic components of the electronic device 100 should be prevent from activating, the keylock structure 110 can be used to lock the electronic component of the electronic device 100. For the electronic components of the electronic device 100 of the embodiment, a keyboard 160 and a display screen 170 are taken as example to illustrate.

As shown in FIG. 2B, the body 111 of the keylock structure 110 includes an external side and an inner side. The hook 113 of the keylock structure 110 is provided on the inner side. The keylock structure can be combined with the first casing 120 by the hook 113 at the inner side, and also can contact with the external side of the first casing 120 by the inner side. After the keylock structure 110 is assembled to the first casing 120, a proper sliding travel exists (namely the difference value between the length L of the through hole 122 and the width W of the hook 113) via the size relationship between the length L of the through hole 122 of the first casing 120 and the width W of the hook 113. Since the keylock structure 110 is combined with the circuit switch 150, the sliding travel is related to the design of the circuit switch 150 which is, for example, a two-segment switch. When the keylock structure 110 slides to be located, the two-segment switch can be cut off or conducted to start or relieve the locking of the electronic components.

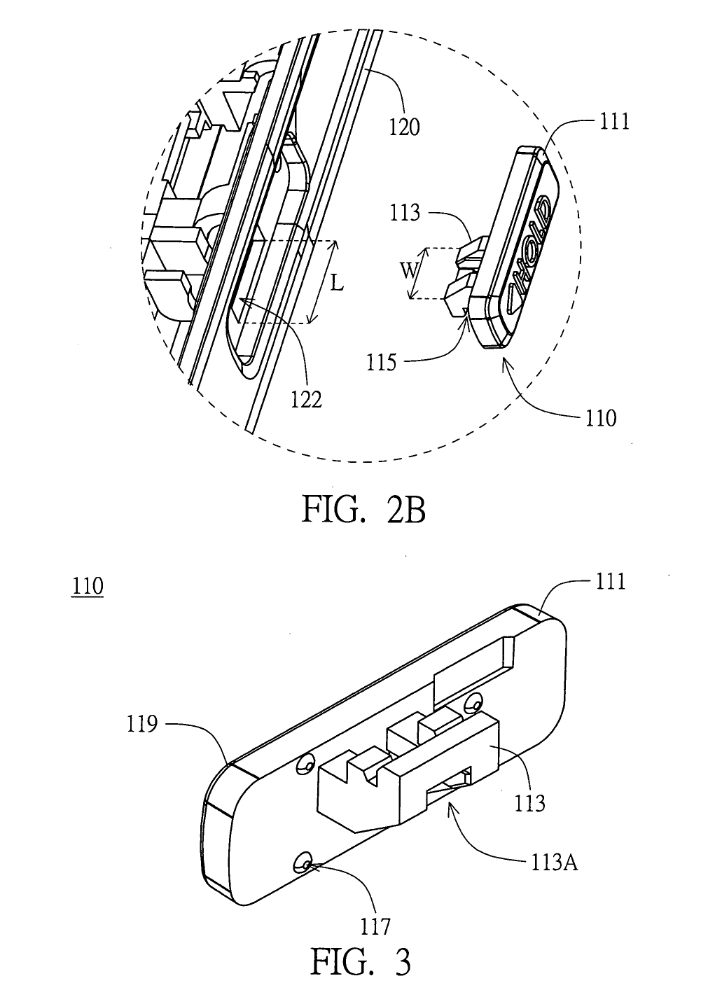

As for other designs of the keylock structure 110, please refer to FIG. 3, which shows a schematic diagram showing the keylock structure shown in FIG. 2A. As shown in FIG. 3, the body 111 of the keylock structure 110 further includes a convex portion 117 including a plurality of circular convex points dispersedly provided on the inner side of the body 111 and used for slidingly contacting with the external side of the first casing 120. The design of the convex portion 117 can decrease the contact area between the keylock structure 110 and the first casing 120, so that the friction area between the keylock structure 110 and the first casing 120 is decreased. The distance between the convex portion 117 and the hook 113 is preferred to be shorter than a half of the length of the body 111 along the sliding direction, so that the portion where the convex portion 117 rubs against the first casing 120 can be shaded by the body 111.

The body 111 of the keylock structure 110 and the hook 113 are preferred to be integrally formed, and the material of them includes, for example, plastic. In addition, a protecting layer 119 can be provided on the external side of the body 111 of the keylock structure 110, and the protecting layer 119 can be formed on the body 111 by electroplating. The material of the protecting layer 119 is, for example, chromium. Pictures or letters (such as HOLD shown in FIG. 2B) can be designed on the protecting layer 119 to illustrate the function of the keylock structure. Certainly, the whole formative aspect of the electronic device 100 can be improved.

In the embodiment, although the convex portion 117 is illustrated by a plurality of circular convex points, they can be replaced by convex strips to be medium of the sliding contact between the keylock structure 110 and the first casing 120.

In addition, the hook 113 of the keylock structure 110 further includes a recess 113A, the position of the recess 113A on the hook 113 is configured according to the circuit switch 150. When the second casing 130 is assembled to the first casing 120, the circuit switch 150 in the second casing 130 is embedded into the recess 113A, so that circuit switch 150 is combined with the hook 113 of the keylock structure 110. A user can drive the circuit switch 150 by sliding the keylock structure 110, and then the keyboard 160 or the display screen 170 of the electronic device 100 can be directly locked or unlocked.

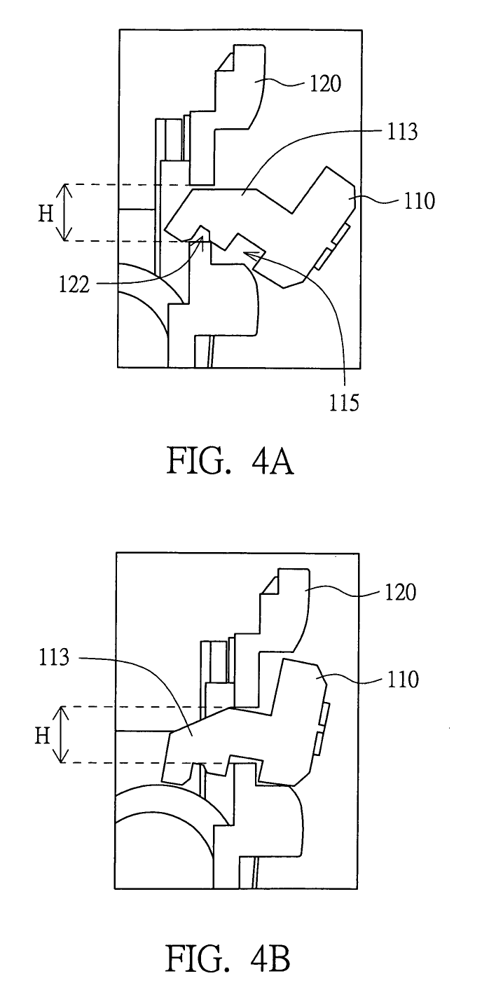

The appended drawings illustrate the combination mode of the keylock structure 110 and the first casing 120. Please refer to FIG. 4A and FIG. 4B which are section diagrams showing the keylock structure assembled to the first casing shown in FIG. 2B. As shown in FIG. 4A, the front end of the hook 113 of the keylock structure 110 has a less thickness, and therefore as long as the hook 113 slopes to an angle, it can pass the through hole 122 easily. When the keylock structure 110 is continuously pushed to make the hook 114 keep on passing through the through hole 122, the casing plate of the first casing 120 can be embedded into the concave portion 115 between the hook 113 and the body 111, as shown in FIG. 4B. Since the size of the thickness of the front end of the concave portion 115 of the hook 113 is bigger than the weight H of the through hole 122, so that the hook 113 can be prevented falling from the through hole 122 effectively, and the keylock structure 110 can be located on the first casing 120. In addition, the keylock structure 110 also can smoothly slide relatively to the first casing 120. The hook 113 of the keylock structure 110 and the recess 113A thereof (shown in FIG. 3) are provided in the first casing 120. When the second casing 130 (shown in FIG. 2A) is assembled, the circuit switch 150 (shown in FIG. 2A) of the second casing 130 is made align with the recess 113A. Then, when the second casing 130 is assembled, the circuit switch 150 also can be fixed to the keylock structure 110.

Compared with the conventional method in which the keylock structure is not fixed until the two components are assembled, the keylock structure 110 of the embodiment can be combined with the first casing 120 directly in the assembly via the self structure design, and other material (such as the sticky tape) for fixing the keylock structure in advance is not needed. Since the self of the keylock structure 110 has a locating function, when assembled into the first casing 120, the keylock structure 110 will not fall outward or slope inward, which saves a lot of assembly time, and an assembler do not need to worry about losing the keylock structure 110. Since the keylock structure 110 contacts with the first casing 120 slidingly by the convex portion 117, the appearance friction of the first casing 120 or the keylock structure 110 caused by the contact between the surfaces can be avoided.

The embodiment of the invention discloses a keylock structure and an electronic device using the same. The keylock structure has a hook to be assembled in the electronic device, and the body of the keylock structure has convex portions for sliding on the sliding surface on the casing of the electronic device.

Although the present invention has been described in considerable detail with reference to certain preferred embodiments thereof, the disclosure is not for limiting the scope of the invention. Persons having ordinary skill in the art may make various modifications and changes without departing from the scope and spirit of the invention. Therefore, the scope of the appended claims should not be limited to the description of the preferred embodiments described above

What is claimed is:

1. A keylock structure applied to an electronic device comprising a first casing having a through hole, the keylock structure comprising:
a body; and
a hook connected to the body, wherein a concave portion is formed between the body and the hook, the hook passes through the through hole to make the concave portion fastened at the through hole, and the body is capable of driving the hook to move along the through hole.

2. The keylock structure according to claim 1, wherein the body comprises an external side and an inner side, and the hook is connected to the inner side.

3. The keylock structure according to claim 2, wherein the body further comprises a convex portion provided at the inner side of the body and used for slidingly contacting with the external side of the first casing.

4. The keylock structure according to claim 3, wherein the distance between the convex portion and the hook is less than a half of the length of the body along the sliding direction.

5. The keylock structure according to claim 3, wherein the convex portion comprises a plurality of convex points.

6. The keylock structure according to claim 3, wherein the convex portion comprises at least a convex strip.

7. The keylock structure according to claim 1, wherein the hook further comprises a recess, and the electronic device further comprises a second casing, a circuit board and an circuit switch, and the circuit board and the circuit switch which are electrically connected with each other are provided in the second casing, and when the second casing is assembled on the first casing, the circuit switch is embedded into the recess to make the circuit switch connected with the hook.

8. The keylock structure according to claim 1, wherein the body and the hook are integrally formed.

9. An electronic device comprising:
a first casing having a through hole; and
a keylock structure comprising a body and a hook connected to the body, wherein a concave portion is formed between the body and the hook, the hook passes through the through hole to make the concave portion fastened at the through hole, and the body is capable of driving the hook to move along the through hole.

10. The electronic device according to claim 9, wherein the hook further comprises a recess, and the electronic device further comprises:
a circuit board;
a circuit switch electrically connected to the circuit board; and
a second casing for holding the circuit board and the circuit switch, wherein when the second casing is assembled to the first casing, the circuit switch is embedded into the recess to make the circuit switch connected to the hook.

11. The electronic device according to claim 9, wherein the body comprises an external side and an inner side, and the hook is connected to the inner side.

12. The electronic device according to claim 11, wherein the body further comprises a convex portion provided at the inner side of the body and used for slidingly contacting with the external side of the first casing.

13. The electronic device according to claim 12, wherein the distance between the convex portion and the hook is less than a half of the length of the body along the sliding direction.

14. The electronic device according to claim 12, wherein the convex portion comprises a plurality of convex points.

15. The electronic device according to claim 12, wherein the convex portion comprises at least a convex strip.

16. The electronic device according to claim 9, wherein the body and the hook are integrally formed.
